(19) United States
(12) Patent Application Publication
(10) Pub. No.: US 2010/0006153 A1
(43) Pub. Date: Jan. 14, 2010

(54) HYBRID ORGANIC SOLAR CELLS WITH PHOTOACTIVE SEMINCONDUCTOR NANOPARTICLES ENCLOSED IN SURFACE MODIFIERS

(75) Inventors: Frank Rauscher, Köln (DE); Werner Hoheisel, Köln (DE); Björn Henninger, Köln (DE); Leslaw Mleczko, Dormagen (DE)

Correspondence Address: Hilderbrand, Christa, 875 Third Avenue, 8th Floor, New York, NY, 10022, US

(73) Assignee: BAYER TECHNOLOGY SERVICES GMBH, LEVERKUSEN (DE)

(21) Appl. No.: 12/526,879

(22) PCT Filed: Feb. 19, 2008
(86) PCT No.: PCT/EP08/01252

§ 371 Date: Aug. 12, 2009

(30) Foreign Application Priority Data
Feb. 27, 2007 (DE) 10 2007 009 790.7

(51) Int. Cl. H01L 31/00

(52) U.S. Cl. 136/261

(57) ABSTRACT

The present invention relates to a solar cell in which semiconductor nanoparticles are surrounded by a photoactive surfactant material in the photoactive layer.

The present invention relates to the field of solar cells, especially that of hybrid organic solar cells.

Such solar cells are known, inter alia from U.S. Pat. No. 6,878,871. This document describes a solar cell in which the semiconductor nanoparticles are arranged in the photoactive layer.

These and similar prior art solar cells, however, frequently have only an unsatisfactory power efficiency. One reason for this is that it has been found to be problematic to rapidly separate the excitons (bound electron-hole pairs) generated by absorption of photons at the nanoparticle/polymer interface by efficient charge transfer in order to prevent power-reducing recombination within the solar cell.

It is thus an object of the invention to provide a hybrid organic solar cell which has a higher power efficiency with at least insignificantly worsened, preferably even the same or improved other properties.

To solve this problem, a solar cell according to Claim 1 of the present invention is provided. Accordingly, a solar cell is proposed, comprising at least one type of semiconductor nanoparticle surrounding at least one photoactive surfactant material in at least one part of the photoactive layer.

By virtue of the semiconductor nanoparticles being surrounded by such a surfactant material, a significantly increased rise in efficiency can be detected within a wide range of applications of the present invention which—without being restricted to such a theory—is attributed to the improved charge separation at the interface between nanoparticle and semiconductive organic matrix, for example a semiconductive polymer, within the photoactive layer of the solar cell.

“Photoactive” in the context of the present invention is understood to mean especially that light is absorbed by generation of excitons.

“Surfactant material” in the context of the present invention is understood to mean especially a material which consists essentially of molecules which contain a polar head group (for example—but not restricted to—a carboxyl, amine, thiol, phosphate or sulphate group) and a nonpolar tail group.

“Photoactive surfactant material” in the context of the present invention is understood especially to mean that the at least one surfactant material has a highest occupied molecular orbital (HOMO) and a lowest unoccupied molecular orbital (LUMO) whose energetic position is such that a separation of the charge carriers generated by light absorption into the semiconductor nanoparticle and/or into the surrounding organic matrix is possible (corresponding to what is known in semiconductor technology as a type II heterojunction). In addition, in many applications within the present invention, owing to the properties of the surfactant with regard to hole conductivity and/or electron conductivity, the charge separation of the excitons which result from light absorption within the nanoparticles and/or the surrounding organic matrix, for example a semiconductive polymer, is improved.

At the interface of a type II heterojunction, the material with the energetically lower LUMO is also known as acceptor, and the material with the energetically higher HOMO as donor.

“Semiconductor nanoparticles” in the context of the present invention are understood to mean, in particular, inorganic materials which have an essentially crystalline or approximately crystalline structure, have a band gap of ≧0.5 to ≦3.5 eV and, on average, have a characteristic size dimension in the range of ≧1 nm to ≦50 nm, preferably ≧1.5 nm to ≦40 nm, more preferably ≧2 nm to ≦30 nm. Characteristic size dimension in the context of the present invention is understood to mean the measurement of the nanoparticles which is crucial for their physicochemical properties. This is the diameter in the case of spherical particles, the rod diameter in the case of elongated particles, for example rods, and the arm diameter in the case of multi-armed particles.

The semiconductor nanoparticles are preferably from the group of the II-VI or III-V compound semiconductors (e.g. CdSe, CdTe, InP) and mixtures thereof.

In a preferred embodiment of the present invention, the at least one photoactive surfactant material comprises a p- and/or n-conductive material.

In a preferred embodiment of the present invention, the coverage density of the semiconductor nanoparticle surface with at least one photoactive surfactant material is ≧50% to ≦100%, more preferably ≧80% to ≦100%, most preferably ≧95% to ≦100%.

A coverage density of 100% means in particular that the surrounding organic matrix has no direct contact to the semiconductor nanoparticles.

The molar proportions of the p- and/or n-conductive materials in the photoactive surfactant material may vary between 0% and 100%, but preferably between 20% and 80%. More preferably, the ratio of the molar proportions of the p- and n-conductive materials in the photoactive surfactant material is inversely proportional to the ratio of the absorption (optical density) of the p- and n-conductive components of the overall solar cell according to the formula

$$\frac{{n}_{p}}{{n}_{n}} = A \cdot \frac{{a}_{n}}{{a}_{p}} \cdot \frac{{σ}_{n}}{{σ}_{p}} ,$$

wherein nₚ is the molar amount of the p-conductive material, nₙ is the molar amount of the n-conductive material in the photoactive surfactant material, correspondingly a_{n or p} is the absorption of the n- or p-conductive material n of the solar cell and σ_{n or p} is the conductivity of the n- and p-conductive photoactive surfactant material, and where the factor A is ≧0.05 and ≦20, preferably ≧0.5 to ≦1.5 and more preferably ≧0.8 to ≦1.2.

As a result, it is possible in many applications within the present invention to improve the efficiency of transport of the charge carriers in the required direction (electrons in the direction of n-conductors, holes in the direction of p-conductors).

In the case that, for example, the p-conductive polymer has a higher absorption, it is desired in a preferred embodiment of the present invention that electrons are transferred to the n-conductive semiconductor nanoparticle to an enhanced degree, and a higher proportion of n-conductive, photoactive surfactant material is thus preferable. In the case that the p-conductive polymer has a lower absorption than the n-conductive semiconductor nanoparticles, it behaves in the reverse manner in a preferred embodiment of the present invention. The procedure should be analogous in a preferred embodiment of the present invention if the polymer is n-conductive and the semiconductor nanoparticles are p-conductive.

In a preferred embodiment of the present invention, the semiconductor nanoparticles are embedded in a photoactive organic matrix.

A photoactive organic “matrix” in the context of the present invention is understood in particular to mean that a semiconductive organic material with a suitable band gap and suitable HOMO-LUMO positions envelops the nanoparticles completely apart from contact regions between the nanoparticles and contact regions to charge-dissipating electrodes. A suitable band gap is possessed by the material when the contact with the semiconductor nanoparticles used gives rise to the type II heterojunction known to those skilled in the art. In a preferred embodiment, the energy difference between the LUMO of the acceptor and the HOMO of the donor and hence the theoretically achievable terminal voltage of the solar cell are as high as possible.

In the case that the acceptor has a higher absorption than the donor, in a preferred embodiment, the energy difference between the HOMO of the acceptor and the HOMO of the donor minus the exciton binding energy is between ≧0.01 eV and ≦0.6 eV; this energy difference is more preferably between ≧0.05 eV and ≦0.3 eV.

In the case that the donor has a higher absorption than the acceptor, in a preferred embodiment, the energy difference between the LUMO of the acceptor and the LUMO of the donor minus the exciton binding energy is between ≧0.01 eV and ≦0.6 eV, this energy difference is more preferably between ≧0.05 eV and ≦0.3 eV.

In a preferred embodiment of the invention, the organic matrix comprises at least one photoactive, semiconductive organic substance. In this case, the (1) semiconductor nanoparticles may usually be n-semiconductive and the organic matrix usually p-conductive, or (2) vice versa.

In order to ensure electron flow in the cathode direction, the LUMO of the surfactant material must be at a higher energy than that of the usually n-conducting material but lower than the LUMO minus the exciton binding energy of the usually p-conductive material, such that electrons can be discharged into the n-conductive material. Equally, the HOMO of the surfactant material must be at a higher energy than that of the usually n-conductive material but lower than that of the usually p-conductive material, such that holes can flow into the organic matrix and hence in the anode direction. The position of the LUMO of the surfactant material in the first case (1) is preferably close to that of the semiconductor nanoparticle, in order that the surfactant material constitutes a very low energetic barrier for the transport of electrons from one particle to the next up to the cathode. The energetic separation of the LUMOs of surfactant (the LUMO of the surfactant being slightly higher) and n-conductive nanoparticle is preferably ≦0.6 eV, more preferably ≦0.3 eV and most preferably ≦0.1 eV. In any case, however, the difference between the LUMOs of p-conductive polymer and n-conductive nanoparticle or surfactant must be sufficiently great that the energy difference is sufficient to bring about separation of the bound electron-hole pair (exciton) generated in the absorbing material. Correspondingly, the position of the HOMO in the second case (2) is preferably close to that of the semiconductor nanoparticle in order that the surfactant material has a very low energetic barrier for the transport of the holes from one particle to the next up to the anode. The energetic separation of the HOMOs is preferably ≦0.6 eV, more preferably ≦0.3 eV and most preferably ≦0.1 eV.

According to the invention, the arrangement of the energy levels of the surfactant materials and of the nanoparticles relative to one another is preferably selected such that:

$$\frac{Δ {E}_{surfactant}}{Δ {E}_{nano}} \geq \frac{HOMO ( nano ) + X - LUMO ( nano )}{HOMO ( nano ) + Y - LUMO ( nano )} for p \text{-} conductive surfactant materials and \text{/} or$$

$$\frac{Δ {E}_{surfactant}}{Δ {E}_{nano}} \geq \frac{HOMO ( nano ) - X - LUMO ( nano )}{HOMO ( nano ) - Y - LUMO ( nano )} for n \text{-} conductive surfactant materials$$

where Y is selected within a range of 0≦y≦1.5 eV, more preferably 0.1≦y≦0.8 eV, and X within a range of 0≦X≦1 eV, more preferably 0.1≦X≦0.5 eV.

In a further preferred embodiment, the surfactant material absorbs at least in part of the wavelength range in which sunlight has a high intensity (400 nm to 1000 nm), with an absorption of ε≧10⁻⁴ nm⁻¹, preferably ε≧10⁻³ nm⁻¹, more preferably ε≧10⁻² nm⁻¹ and hence contributes actively to the generation of excitons in the photoactive layer of the solar cell. At the same time, the absorption is related to the unitless optical density OD in the relationship OD=ε·d. The symbol d corresponds here to the layer thickness of the surfactant material around the semiconductor nanoparticles.

In a preferred embodiment of the present invention, the matrix comprises an organic polymer. This has been found to be advantageous in many applications of the present invention in that it is thus possible in a simple manner to build up the desired solar cell, for example, by printing or casting processes.

General group definitions: within the description and the claims, general groups, for example alkyl, alkoxy, aryl etc., are claimed and described. Unless stated otherwise, the following groups are preferably used within the generally described groups in the context of the present invention:

alkyl: linear and branched C1-C8-alkyls,
long-chain alkyls: linear and branched C5-C20-alkyls,
alkenyl: C2-C8-alkenyl,
cycloalkyl: C3-C8-cycloalkyl,
alkoxy: C1-C6-alkoxy,
long-chain alkoxy: linear and branched C5-C20-alkoxy,
alkylene: selected from the group comprising:
methylene; 1,1-ethylene; 1,2-ethylene; 1,1-propylidene; 1,2-propylene; 1,3-propylene; 2,2
-propylidene; butan-2-ol-1,4-diyl; propan-2-ol-1,3-diyl; 1,4-butylene; cyclohexane-1,1-diyl;
cyclohexane-1,2-diyl; cyclohexane-1,3-diyl; cyclohexane-1,4-diyl; cyclopentane-1,1-diyl;
cyclopentane-1,2-diyl; and cyclopentane-1,3-diyl,
aryl: selected from aromatics having a molecular weight below 300 Da,
arylene: selected from the group comprising: 1,2-phenylene; 1,3-phenylene; 1,4-phenylene; 1,2-naphthalenylene; 1,3-naphthalenylene; 1,4-naphthalenylene; 2,3-naphthalenylene; 1-hydroxy-2,3-phenylene; 1-hydroxy-2,4-phenylene; 1-hydroxy-2,5-phenylene; and 1-hydroxy-2,6-phenylene,
heteroaryl: selected from the group comprising: pyridinyl; pyrimidinyl; pyrazinyl; triazolyl; pyridazinyl; 1,3,5-triazinyl; quinolinyl; isoquinolinyl; quinoxalinyl; imidazolyl; pyrazolyl; benzimidazolyl; thiazolyl; oxazolidinyl; pyrrolyl; thiophenyl; carbazolyl; indolyl; and isoindolyl, where the heteroaryl may be bonded to the compound via any atom in the ring of the selected heteroaryl,
heteroarylene: selected from the group comprising: pyridinediyl; quinolinediyl; pyrazodiyl; pyrazolediyl; triazolediyl; pyrazinediyl, thiophenediyl; and imidazolediyl, where the heteroarylene functions as a bridge in the compound via any atom in the ring of the selected heteroaryl; especially preferred are: pyridine-2,3-diyl; pyridine-2,4-diyl; pyridine-2,5-diyl; pyridine-2,6-diyl; pyridine-3,4-diyl; pyridine-3,5-diyl; quinoline-2,3-diyl; quinoline-2,4-diyl; quinoline-2,8-diyl; isoquinoline-1,3-diyl; isoquinoline-1,4-diyl; pyrazole-1,3-diyl; pyrazole-3,5-diyl; triazole-3,5-diyl; triazole-1,3-diyl; pyrazine-2,5-diyl; and imidazole-2,4-diyl, thiophene-2,5-diyl, thiophene-3,5-diyl; a C1-C6-heterocycloalkyl selected from the group comprising: piperidinyl; piperidine; 1,4-piperazine, tetrahydrothiophene; tetrahydrofuran; 1,4,7-triazacyclononane; 1,4,8,11-tetraazacyclotetradecane; 1,4,7,10,13-pentaazacyclopentadecane; 1,4-diaza-7-thia-cyclononane; 1,4-diaza-7-oxacyclononane; 1,4,7,10-tetraazacyclododecane; 1,4-dioxane; 1,4,7-trithiacyclononane; pyrrolidine; and tetrahydropyran, where the heteroaryl may be bonded to the C1-C6-alkyl via any atom in the ring of the selected heteroaryl,
heterocycloalkylene: selected from the group comprising: piperidin-1,2-ylene; piperidin-2,6-ylene; piperidin-4,4-ylidene; 1,4-piperazin-1,4-ylene; 1,4-piperazin-2,3-ylene; 1,4-piperazin-2,5-ylene; 1,4-piperazin-2,6-ylene; 1,4-piperazin-1,2-ylene; 1,4-piperazin-1,3-ylene; 1,4-piperazin-1,4-ylene; tetrahydrothiophen-2,5-ylene; tetrahydrothiophen-3,4-ylene; tetrahydrothiophen-2,3-ylene; tetrahydrofuran-2,5-ylene; tetrahydrofuran-3,4-ylene; tetrahydrofuran-2,3-ylene; pyrrolidin-2,5-ylene; pyrrolidin-3,4-ylene; pyrrolidin-2,3-ylene; pyrrolidin-1,2-ylene; pyrrolidin-1,3-ylene; pyrrolidin-2,2-ylidene; 1,4,7-triazacyclonon-1,4-ylene; 1,4,7-triazacyclonon-2,3-ylene; 1,4,7-triazacyclonon-2,9-ylene; 1,4,7-triazacyclonon-3,8-ylene; 1,4,7-triazacyclonon-2,2-ylidene; 1,4,8,11-tetraazacyclotetradec-1,4-ylene; 1,4,8,11-tetraazacyclotetradec-1,8-ylene; 1,4,8,11-tetraazacyclotetradec-2,3-ylene; 1,4,8,11-tetraazacyclotetradec-2,5-ylene; 1,4,8,11-tetraazacyclotetradec-1,2-ylene; 1,4,8,11-tetraazacyclotetradec-2,2-ylidene; 1,4,7,10-tetraazacyclododec-1,4-ylene; 1,4,7,10-tetraazacyclododec-1,7-ylene; 1,4,7,10-tetraazacyclododec-1,2-ylene; 1,4,7,10-tetraazacyclododec-2,3-ylene; 1,4,7,10-tetraazacyclododec-2,2-ylidene; 1,4,7,10,13-pentaazacyclopentadec-1,4-ylene; 1,4,7,10,13-pentaazacyclopentadec-1,7-ylene; 1,4,7,10,13-pentaazacyclopentadec-2,3-ylene; 1,4,7,10,13-pentaazacyclopentadec-1,2-ylene; 1,4,7,10,13-pentaazacyclopentadec-2,2-ylidene; 1,4-diaza-7-thia-cyclonon-1,4-ylene; 1,4-diaza-7-thiacyclonon-1,2-ylene; 1,4-diaza-7-thiacyclonon-2,3-ylene; 1,4-diaza-7-thiacyclonon-6,8-ylene; 1,4-diaza-7-thiacyclonon-2,2-ylidene; 1,4-diaza-7-oxacyclonon-1,4-ylene; 1,4-diaza-7-oxacyclonon-1,2-ylene; 1,4-diaza-7-oxacyclonon-2,3-ylene; 1,4-diaza-7-oxacyclonon-6,8-ylene; 1,4-diaza-7-oxacyclonon-2,2-ylidene; 1,4-dioxan-2,3-ylene; 1,4-dioxan-2,6-ylene; 1,4-dioxan-2,2-ylidene; tetrahydropyran-2,3-ylene; tetrahydropyran-2,6-ylene; tetrahydropyran-2,5-ylene; tetrahydropyran-2,2-ylidene; 1,4,7-trithiacyclonon-2,3-ylene; 1,4,7-trithiacyclonon-2,9-ylene; and 1,4,7-trithia-cyclonon-2,2-ylidene,
heterocycloalkyl: selected from the group comprising: pyrrolinyl; pyrrolidinyl; morpholinyl; piperidinyl; piperazinyl; hexamethyleneimine; 1,4-piperazinyl; tetrahydrothiophenyl; tetrahydrofuranyl; 1,4,7-triazacyclononanyl; 1,4,8,11-tetraazacyclotetradecanyl; 1,4,7,10,13-pentaazacyclopentadecanyl; 1,4-diaza-7-thiacyclononanyl; 1,4-diaza-7-oxa-cyclononanyl; 1,4,7,10-tetraazacyclododecanyl; 1,4-dioxanyl; 1,4,7-trithiacyclononanyl; tetrahydropyranyl; and oxazolidinyl, where the heterocycloalkyl may be bonded to the compound via any atom in the ring of the selected heterocycloalkyl,
halogen: selected from the group comprising: F; Cl; Br and I,
haloalkyl: selected from the group comprising mono-, di-, tri-, poly- and perhalogenated linear and branched C1-C8-alkyl,
pseudohalogen: selected from the group comprising —CN, —SCN, —OCN, N3, —CNO, —SeCN.

Unless stated otherwise, the following groups are more preferred groups within the general group definitions:

alkyl: linear and branched C1-C6-alkyl,
long-chain alkyls: linear and branched C5-C10-alkyl, preferably C6-C8-alkyls,
alkenyl: C3-C6-alkenyl,
cycloalkyl: C6-C8-cycloalkyl,
alkoxy: C1-C4-alkoxy,
long-chain alkoxy: linear and branched C5-C10-alkoxy, preferably linear C6-C8-alkoxy,
alkylene: selected from the group comprising: methylene; 1,2-ethylene; 1,3-propylene; butan-2-ol-1,4-diyl; 1,4-butylene; cyclohexane-1,1-diyl; cyclohexane-1,2-diyl; cyclohexane-1,4-diyl; cyclopentane-1,1-diyl; and cyclopentane-1,2-diyl,
aryl: selected from the group comprising: phenyl; biphenyl; naphthalenyl; anthracenyl; and phenanthrenyl,
arylene: selected from the group comprising: 1,2-phenylene; 1,3-phenylene; 1,4-phenylene; 1,2-naphthalenylene; 1,4-naphthalenylene; 2,3-naphthalenylene and 1-hydroxy-2,6-phenylene,
heteroarylene: thiophene, pyrrole, pyridine, pyridazine, pyrimidine, indole, thienothiophene,
halogen: selected from the group comprising: F and Cl.

In a preferred embodiment of the present invention, the matrix comprises an organic polymer of the structure

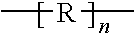

where each R is independently selected from the group comprising unsubstituted, alkyl-substituted and/or alkoxy-substituted arylenes and alkyl-substituted and/or alkoxy-substituted heteroarylenes, and n≧2, preferably n≧4 to ≦400.

In a preferred embodiment of the present invention, the matrix comprises an organic polymer of the structure

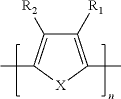

where each X for each unit is independently selected from the group comprising N, O, P, S, R₁ and R₂ for each unit is selected independently from the group comprising hydrogen, alkyl, alkoxy, and n is ≧4 to ≦500, preferably ≧15 to ≦400, more preferably ≧20 to ≦300.

In a preferred embodiment of the present invention, the matrix comprises an organic polymer of the structure

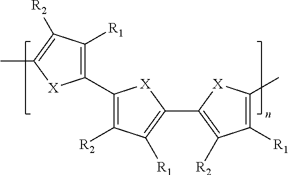

where each X for each unit is independently selected from the group comprising N, O, P, S, R₁ and R₂ for each unit are selected independently from the group comprising hydrogen, alkyl, alkoxy, and n is ≧4 to ≦300, preferably ≧15 to ≦250, more preferably ≧20 to ≦150.

In a preferred embodiment of the present invention, the matrix comprises an organic polymer of the structure

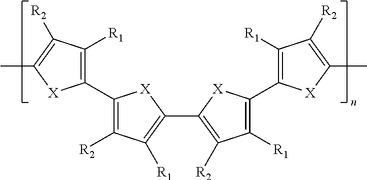

where each X for each unit is independently selected from the group comprising N, O, P, S, R₁ and R₂ for each unit are selected independently from the group comprising hydrogen, alkyl, alkoxy, and n is ≧4 to ≦300, preferably ≧15 to ≦250, more preferably ≧20 to ≦150.

In a preferred embodiment of the present invention, the volume ratio VA of semiconductor nanoparticles, plus the surrounding surfactant material to form the photoactive layer, is:

$$VA = \frac{{V}_{nano} + {V}_{surfactant}}{{V}_{active layer}}$$

and is selected such that VA is ≧0.1, preferably ≧0.2 to ≦0.74, and more preferably ≧0.35 to ≦0.6.

The proportion by volume VA of the semiconductor nanoparticles plus the surrounding surfactant material in the photoactive layer is, in a preferred embodiment, high enough to ensure sufficient percolation paths to the corresponding electrode for discharge of the electrons through the n-conductive material, or of the holes through the p-conductive material. In a preferred embodiment of the present invention, the proportion by volume of the semiconductor nanoparticles plus the surrounding surfactant material is at least sufficiently high that the mean distance from the site of formation of an electron-hole pair to the closest polymer-nanoparticle interface is not greater than the diffusion length of the electron-hole pair which is approx. 5-30 nm.

The optimal proportion by volume depends in many applications especially also on the morphology of the semiconductor nanoparticles. The greater the exciton diffusion length is, and the more particles deviate from the spherical shape, the lower it is. For spherical particles, in a preferred embodiment, it is between ≧0.2 and ≦0.7 and more preferably between ≧0.3 and ≦0.65. For rod-shaped particles having an axis ration of at least 3:1 it is preferably between ≧0.15 and ≦0.65 and more preferably between ≧0.25 and ≦0.6, the lower limit of the proportion by volume (≧0.25 to ≦0.45) being favourable in the case of a larger axis ratio (>5:1). For polypodal-shaped particles it should preferably be between ≧0.1 and ≦0.6 and more preferably between ≧0.2 and ≦0.5, and the axis ratio of the branches of the polypodes should be at least 3:1. At an axis ratio of at least 5:1, the lower limit of the proportion by volume is favourable (≧0.1 to ≦0.4).

With these limits, in a multitude of applications within the present invention, the above requirement regarding the percolation paths is also met. Too high a proportion by volume of semiconductor nanoparticles can reduce the proportion of the polymer featuring absorption in a particular wavelength range. Therefore, in a preferred embodiment of the present invention, the proportion by volume of nanoparticles should be at most≦60%. The total absorption of the solar cell in a multitude of applications within the present invention will overall, in all probability and without being fixed thereto, be determined by the composition of the three photoactive components (organic matrix, surfactant material, semiconductor nanoparticles), their proportions by volume relative to one another and their layer thickness.

In a preferred embodiment of the present invention, the surfactant material comprises a p-conductive material, which has a hole mobility of ≧0.001 cm²/Vs to ≦10 cm²/Vs, preferably of ≧0.01 cm²/Vs to ≦5 cm²/Vs, more preferably of ≧0.05 cm²/Vs to ≦2 cm²/Vs.

The at least one surfactant material preferably comprises at least one p-conductive material of the structure

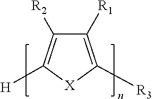

where each X for each unit is independently selected from the group consisting of N, O, P, S, R₁ and R₂ for each unit are selected independently from the group comprising hydrogen, alkyl, alkoxy, R₃ is selected from the group comprising carboxylate, amines, thiols, phosphate, sulphate and n is ≧3 to ≦15.

In a preferred embodiment of the present invention, the surfactant material comprises an n-conductive material, and the mobility within the surfactant material is preferably ≧0.00001 cm²/Vs to ≦10 cm²/Vs, preferably ≧0.001 cm²/Vs to ≦5 cm²/Vs, more preferably ≧0.01 cm²/Vs to ≦5 cm²/Vs.

The at least one surfactant material preferably comprises at least one n-conductive material of the structure

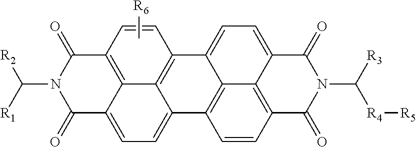

where R₁, R₂, R₃ and R₆ are selected independently from the group comprising hydrogen, alkyl, alkoxy, R₄ is a single bond or an alkylene unit, and R₅ is selected from the group comprising carboxylate, amines, thiols, phosphate, sulphate.

The at least one surfactant material preferably comprises at least one n-conductive material of the structure

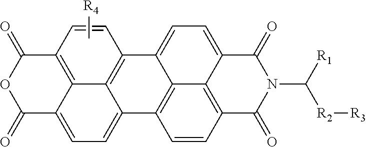

where R₁ and R₄ are selected independently from the group comprising hydrogen, alkyl, alkoxy, R₂ is a single bond and/or an alkylene unit, and R₃ is selected from the group comprising carboxylate, amines, thiols, phosphate, sulphate.

In a preferred embodiment of the present invention, the surfactant material comprises at least one material having a solubility of ≧10 g/l to ≦400 g/l in at least one solvent having an E_{T}(30) value of ≧30 to ≦42.

“E_{T}(30) value” is understood to mean the polarity of a solvent based in the context of the present invention on the values which have been published in Reichart; Dimroth, Fortschr. Chem. Forsch. 1969, 11, 1-73, Reichart, Angew. Chem. 1979, 91, 119-131, and cited in March, Advanced Organic Chemistry, 4th edition, J. Wiley & Sons, 1992, Table 10.13, p. 361.

The present invention also relates to the use of a solar cell according to the present invention for portable electronic applications (e.g. mobile phones, MP3 players, notebooks, medical technology, etc.), for use in the automobile sector for generating electricity for various electrical loads, for the use of semi-transparent solar cells in glazing for buildings, greenhouses or automobiles, in watches, design objects, for the use of such a solar cell in the form of a fully flexible and freely shapeable film, for stationary energy generation in the form of roof and wall installations, or films for incorporation into items of clothing.

The aforementioned components and those claimed and described in the working examples for use in accordance with the invention, in terms of their size, configuration, material selection and technical design, are not subject to any particular exceptional conditions, such that the selection criteria known in the field of use can find use without restriction.

Further details, features and advantages of the subject matter of the invention are evident from the subclaims and from the description which follows of the accompanying drawings, in which—by way of example—several working examples of an inventive solar cell are shown. In the drawings:

FIG. 1 shows a very schematic sectional view through a solar cell according to a first embodiment of the invention;

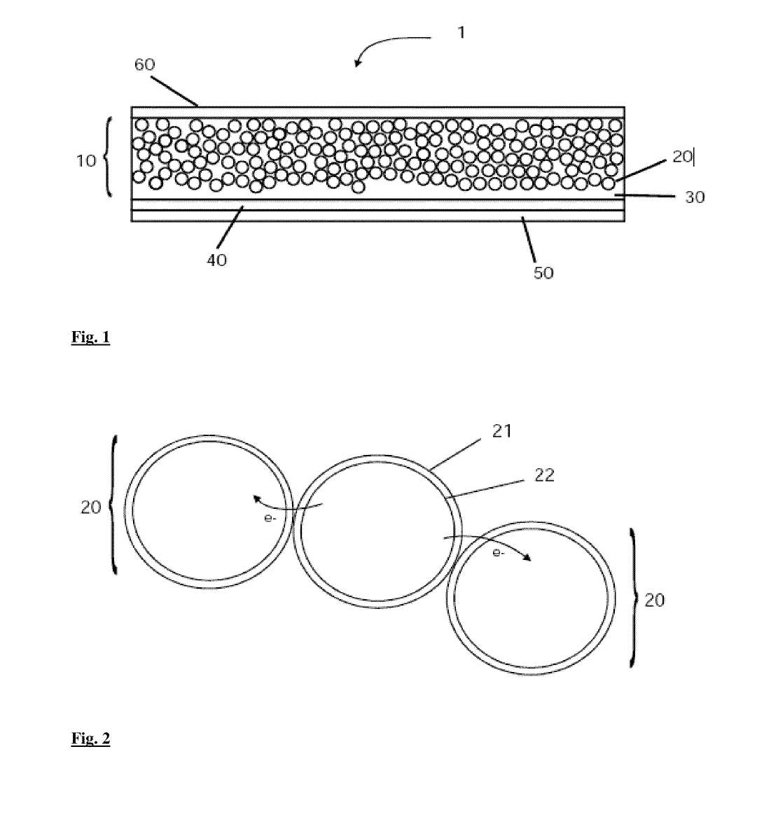

FIG. 2 shows a very schematic sectional view through several semiconductor nanoparticles of the solar cell from FIG. 1, surrounded by surfactant material; and

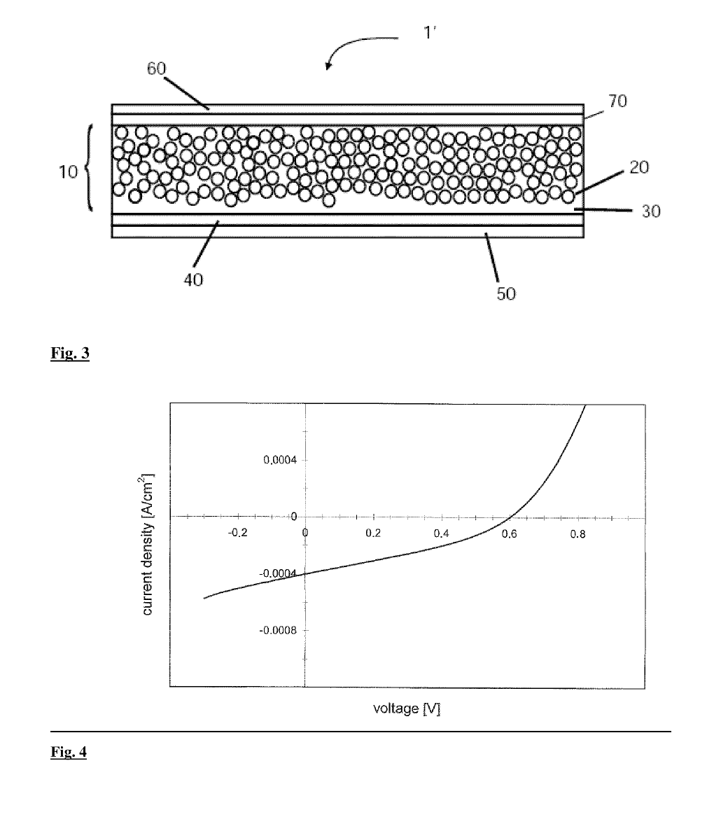

FIG. 3 shows a very schematic sectional view through a solar cell according to a second embodiment of the invention.

FIG. 4 shows a diagram of a typical current-voltage characteristic for a solar cell according to Example 1.

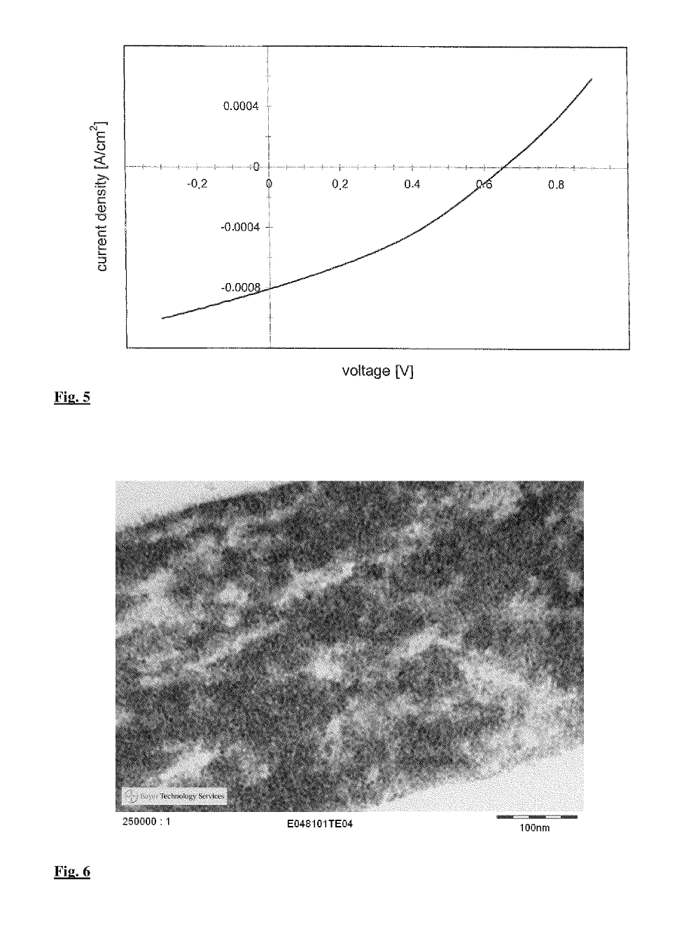

FIG. 5 shows a diagram of a typical current-voltage characteristic for a solar cell according to Example 2.

FIG. 6 shows a transmission electron micrograph of a cross section of a solar cell according to the second embodiment of the invention.

FIG. 1 shows a very schematic sectional view through a solar cell 1 according to a first embodiment of the invention. The solar cell comprises a first electrode 50 which, in the present embodiment, consists of a transparent material, for instance an ITO. In principle, though, all materials known in the field are useful here, especially so-called TCO (Transparent Conductive Oxides), but also functionalized SWCNTs (Single Wall Carbon Nanotubes) applied in thin layers or functionalized MWCNTs (Multi Wall Carbon Nanotubes).

Applied to the solar cell is a layer of a first p-conductive polymer 40. The layer is about 40 nm thick and consists, in this embodiment, essentially of PEDOT:PSS. Here too, though, all materials known in the field which have electron-blocking properties and are transparent to light in the relevant wavelength ranges are useful, for instance the PEDOT:PSS mentioned or HIL.

The photoactive layer 10 consists, in the present embodiment, of a layer of the inventive semiconductor nanoparticles 20 coated with photoactive surfactant material, which are embedded into the matrix material.

Additionally applied is a layer 30 (whose thickness is 10 nm or less) which consists of pure matrix material. This prevents a possible short-circuit between the semiconductor nanoparticles 20 and the p-conductive polymer 40. The matrix material in this embodiment is P3HT (poly-3-hexylthiophene). Likewise useful here are the abovementioned polymers. For the layer thickness, the product of total absorption of the solar cell and of the electron conductivity and the hole conductivity, caused by the formation of sufficiently effective percolation paths for discharge of the electrons through the n-conductive material or of the holds of the p-conductive material, is at a maximum.

This is followed by a layer of the inventive semiconductor nanoparticles 20 surrounded by photoactive surfactant material, which are embedded into the matrix material. It should be pointed out that especially this section of the figure is drawn very schematically. The actual size ratios, proportions by volume and morphologies will be very different according to the specific application.

Finally, a second electrode 60 is applied on the photoactive layer 10, which, in the present embodiment, consists essentially of aluminium.

FIG. 2 shows a very schematic sectional view through several semiconductor nanoparticles 20 of the solar cell from FIG. 1 surrounded by surfactant material. In this drawing, it can be seen (very schematically) that the semiconductor nanoparticles consist of semiconductor material 21 surrounded by photoactive surfactant material 22. When excitons are generated by incidence of light through absorption of photons and the bound electron-hole pairs diffuse to the nanoparticle/polymer interface it is now possible (as indicated by the arrow in the Fig.) for more efficient charge separation through the photoactive surfactant material 22 to take place, which increases the efficiency of the solar cell.

In a specific embodiment, the semiconductor nanoparticles consist essentially of CdSe and are surrounded by a mixture of an n-conductive surfactant material, which consists of an end-phosphated polythiophene and a p-conductive perylene material.

It should be pointed out clearly that FIG. 2 is also a very schematic drawing. In real systems, the size ratios will differ significantly from those of FIG. 2, since the semiconductor particles 21 are preferably surrounded by a monolayer of the photoactive material 22.

Moreover, it should be pointed out that, although the semiconductor particles 21 in FIG. 1 and FIG. 2 have been shown with a round diameter, all conceivable morphologies are possible for the semiconductor particles and may also be preferred according to the specific application of the invention.

For instance, the semiconductor particles consist of rods (i.e. are essentially one-dimensional) in a preferred embodiment, have a leaf-like structure (i.e. are essentially two-dimensional) in a further embodiment, or have a three-dimensional shape which may be circular, approximately ellipsoidal and/or have a tetrapodal form.

It should be pointed out that, according to the application, semiconductor particles of different morphologies may also be present in the photoactive layer.

FIG. 3 shows a very schematic sectional view through a solar cell 1′ according to a second embodiment of the invention. This version differs from that of FIG. 1 in that a further layer 70 (a so-called “hole-blocking layer”, e.g. phenyl C61 butyric acid methyl ester) has been applied, which prevents unwanted transition of holes into the aluminium electrode.

FIG. 4 shows a diagram of a typical current-voltage characteristic for a solar cell according to Example 1 under illumination conditions which correspond approximately to the radiation spectrum at 1.5 AM. The characteristic was recorded for a solar cell consisting of CdSe nanoparticles and P3HT.

FIG. 5 shows a diagram of a typical current-voltage characteristic for a solar cell according to Example 2 under illumination conditions which correspond approximately to the radiation spectrum at 1.5 AM. The characteristic was recorded for a solar cell consisting of CdSe nanoparticles, photoactive surfactant material and P3HT.

FIG. 6 shows a transmission electron micrograph of a cross section of a solar cell according to the second embodiment of the invention, consisting of CdSe nanoparticles, photoactive surfactant material and P3HT.

### EXAMPLE

### Example 1

### Workup of CdSe Nanoparticles in Pyridine and Production of a CdSe/P3Ht Solar Cell

To remove the surfactant which is used in the synthesis of the CdSe nanoparticles, 35 mg of the CdSe nanoparticles are redispersed first in 2 ml of toluene and then in 20 ml of pyridine (toluene to pyridine ratio: 1/10). Boiling (temperature approx. 117° C. for 2 h) under reflux and inert atmosphere causes exchange of the ligands, such that pyridine for the most part replaces the surfactants present at the surface of the nanoparticles. The subsequent precipitation of the pyridine-coated nanoparticles is effected with 200 ml of n-hexane (pyridine to n-hexane ratio: 1/10). This step is simultaneously also a test for successful ligand exchange. The sedimented CdSe nanoparticles are removed by centrifugation (for 1 h at an acceleration of approx. 2200 g) from the excess solvent and surfactant mixture. For further purification, the nanoparticles can then be redispersed again in 3 ml of pyridine and precipitated in 30 ml of n-hexane. Excess solvent and surfactant fractions are removed by centrifugation (for 10 min at an acceleration of approx. 2200 g). After the last purification step, the pyridine-coated CdSe nanoparticles are redispersed in a mixture consisting of 7% by volume of pyridine in chlorobenzene (volume used approx. 1 ml). 180 μl of a P3HT/chlorobenzene solution (50 mg/ml) are then added to this mixture. This solution can then be utilized for the production of solar cells, a mass ratio of CdSe nanoparticles to P3HT of 90/10 being present in the solution.

The solar cell is then prepared as follows. The uniform application of the CdSe/P3HT dispersion to a glass plate coated with ITO and PEDOT:PSS is effected by means of a spin-coater at a rotational speed of 15001/min for 30 s. The film thus formed (see FIG. 6) is then heat-treated at 150° C. for 15 min. The back electrode is then applied by vapour deposition of an aluminium layer. The solar cell was then analysed under conditions which correspond approximately to the radiation spectrum at 1.5 AM.

### Example 2

### Workup of CdSe Nanoparticles in Pyridine and Photoactive Surfactant Material and Production of a CdSe/Photoactive Surfactant Material/P3Ht Solar Cell

To remove the surfactant which is used in the synthesis of the CdSe nanoparticles, 35 mg of the CdSe nanoparticles are redispersed first in 2 ml of toluene and then in 20 ml of pyridine (toluene to pyridine ratio: 1/10). Boiling (temperature approx. 117° C. for 2 h) under reflux and inert atmosphere causes exchange of the ligands, such that pyridine for the most part replaces the surfactants present at the surface of the nanoparticles. The subsequent precipitation of the pyridine-coated nanoparticles is effected with 200 ml of n-hexane (pyridine to n-hexane ratio: 1/10). This step is simultaneously also a test for successful ligand exchange. The sedimented CdSe nanoparticles are removed by centrifugation (for 1 h at an acceleration of approx. 2200 g) from the excess solvent and surfactant mixture. For further purification, the nanoparticles can then be redispersed again in 3 ml of pyridine and in precipitated 30 ml of n-hexane.

The last purification step is followed by the redispersion of the pyridine-coated CdSe nanoparticles in a mixture consisting of 9% by volume of pyridine in chlorobenzene (volume used approx. 3 ml). By means of evaporative concentration with nitrogen, the mixture of CdSe nanoparticles, pyridine and chlorobenzene is adjusted to a particle concentration of approx. 25 mg/ml. This is followed by the addition of 76 μl of a P3HT/chlorobenzene solution (50 mg/ml) and 77 μl of a solution of photoactive surfactant material and chlorobenzene (50 mg/ml). This solution can then be utilized for the production of solar cells, a mass ratio of CdSe nanoparticles to photoactive surfactant material and P3HT of 82/9/9 being present in the solution.

The solar cell is then prepared as follows. The uniform application of the CdSe/P3HT dispersion to a glass plate coated with ITO and PEDOT:PSS is effected by means of a spin-coater at a rotational speed of 15001/min for 30 s. The film thus formed (see FIG. 6) is then heat-treated at 150° C. for 15 min. The back electrode is then applied by vapour deposition of an aluminium layer. The solar cell was then analysed under conditions which correspond approximately to the radiation spectrum at 1.5 AM.

1-11. (canceled)

12. A solar cell comprising
at least one semiconductor nanoparticle surrounded by at least one photoactive surfactant material in at least one part of the photoactive layer.

13. The solar cell according to claim 12, wherein the at least one photoactive surfactant material comprises a p- and/or n-conductive material.

14. The solar cell according to claim 12, wherein the semiconductor nanoparticle surface has a coverage density of, in an average, ≧50% to ≦100%.

15. The solar cell according to claim 12, wherein the semiconductor nanoparticles are embedded in a photoactive matrix.

16. The solar cell according to claim 12, wherein the volume ratio VA of semiconductor nanoparticles and the surrounding surfactant material relative to the photoactive layer is
$$VA = \frac{{V}_{nano} + {V}_{surfactant}}{{V}_{active \cdot layer}}$$
≧0.1, preferably ≧0.2 to ≦0.74, and more preferably ≧0.35 to ≦0.6.

17. The solar cell according to claim 12, wherein the surfactant material comprises a p-conductive material and the mobility within the surfactant material is ≧0.001 cm²/Vs to ≦10 cm²/Vs.

18. The solar cell according to claim 12, wherein the surfactant material comprises an n-conductive material and the mobility within the surfactant material is ≧0.00001 cm²/Vs to ≦10 cm²/Vs.

19. The solar cell according to claim 1, wherein the surfactant material comprises at least one material having a solubility of ≧10 g/l to ≦400 g/l in at least one solvent having an ET-value of ≧30 to ≦42.

20. The solar cell according to claim 1, wherein the surfactant material comprises at least one first p-conductive material and at least one second n-conductive material, and the mixing ratio of p-conductive to n-conductive material is 0.2:1 to 4:1.

21. The solar cell according to claim 1, wherein the ratio of the molar proportions of the p- and n-conductive materials in the photoactive surfactant material is inversely proportional to the ratio of the absorption (optical density) of the p- and n-conductive components of the overall solar cell according to
$$\frac{{n}_{p}}{{n}_{n}} = A \cdot \frac{{a}_{n}}{{a}_{p}} \cdot \frac{{σ}_{n}}{{σ}_{p}} ,$$
wherein nₚ is the molar amount of the p-conductive material, nₙ is the molar amount of the n-conductive material in the photoactive surfactant material, correspondingly a_{n or p} is the absorption of the n- or p-conductive material n of the solar cell and σ_{n or p} is the conductivity of the n- and p-conductive photoactive surfactant material, and where the factor A is ≧0.05 and ≦20.

22. A Method for using a solar cell comprising the steps of
providing a solar cell having at least one semiconductor nanoparticle surrounded by at least one photoactive surfactant material in at least one part of the photoactive layer for portable electronic applications.
